(19) United States
(12) Patent Application Publication
(10) Pub. No.: US 2024/0421122 A1
(43) Pub. Date: Dec. 19, 2024

(54) SEMICONDUCTOR DEVICE

(71) Applicant: Kioxia Corporation, Tokyo (JP)

(72) Inventors: Masayuki MIURA, Ota (JP); Kazuma HASEGAWA, Fujisawa (JP); Yuichi SANO, Setagaya (JP)

(73) Assignee: Kioxia Corporation, Tokyo (JP)

(21) Appl. No.: 18/743,211

(22) Filed: Jun. 14, 2024

(30) Foreign Application Priority Data
Jun. 15, 2023 (JP) 2023-098761

(51) Int. Cl. H01L 25/065; H01L 23/00; H01L 23/31; H01L 23/498; H01L 23/528; H10B 80/00

(52) U.S. Cl. CPC H01L 25/0652; H01L 23/3128; H01L 23/49816; H01L 23/5286; H01L 24/08; H01L 24/48; H01L 2224/08155; H01L 2224/08225; H01L 2224/48138; H01L 2224/48227; H01L 2924/0665; H01L 2924/1438; H01L 2924/15311; H01L 2924/182; H10B 80/00

(57) ABSTRACT

A semiconductor device according to an embodiment includes a substrate, a plurality of first semiconductor chips, a plurality of first resins, and a second semiconductor chip. The substrate has a first surface. The plurality of first semiconductor chips are stacked while being displaced in a direction substantially parallel to the first surface. The plurality of first resins are provided on respective lower surfaces of the plurality of first semiconductor chips. The second semiconductor chip is provided on the first surface. At least one of the plurality of first resins is in contact with an upper surface of the second semiconductor chip.

### CROSS REFERENCE TO RELATED APPLICATIONS

This application is based upon and claims the benefit of priority from the prior Japanese Patent Application No. 2023-098761, filed on Jun. 15, 2023, the entire contents of which are incorporated herein by reference.

### FIELD

The embodiments of the present invention relate to a semiconductor device.

### BACKGROUND

In a package structure of a semiconductor device, semiconductor chips whose ratio (aspect ratio) of the width of long sides to the width of the short sides is high are mounted in some cases. It is difficult in some cases to appropriately dispose the semiconductor chips having a high aspect ratio in the semiconductor package.

### BRIEF DESCRIPTION OF THE DRAWINGS

FIG. 1 is a cross sectional view illustrating an example of the configuration of a semiconductor device according to a first embodiment;

FIG. 2 is a top view illustrating the example of the configuration of the semiconductor device according to the first embodiment;

FIG. 3 is a cross sectional view illustrating an example of the configuration of a semiconductor device according to a comparative example of the first embodiment;

FIG. 4 is a cross sectional view illustrating an example of the configuration of a semiconductor device according to a first modification of the first embodiment;

FIG. 5 is a cross sectional view illustrating an example of the configuration of a semiconductor device according to a second modification of the first embodiment;

FIG. 6 is a cross sectional view illustrating an example of the configuration of a semiconductor device according to a third modification of the first embodiment;

FIG. 7 is a cross sectional view illustrating an example of the configuration of a semiconductor device according to a fourth modification of the first embodiment;

FIG. 8 is a cross sectional view illustrating an example of the configuration of a semiconductor device according to a fifth modification of the first embodiment;

FIG. 9 is a cross sectional view illustrating an example of the configuration of a semiconductor device according to a sixth modification of the first embodiment;

FIG. 10 is a cross sectional view illustrating an example of the configuration of a semiconductor device according to a second embodiment;

FIG. 11 is a top view illustrating the example of the configuration of the semiconductor device according to the second embodiment;

FIG. 12 is a cross sectional view illustrating an example of the configuration of a semiconductor device according to a first modification of the second embodiment;

FIG. 13 is a cross sectional view illustrating the example of the configuration of a semiconductor device according to a second modification of the second embodiment;

FIG. 14 is a cross sectional view illustrating an example of the configuration of a semiconductor device according to a third modification of the second embodiment;

FIG. 15 is a cross sectional view illustrating an example of the configuration of a semiconductor device according to a fourth modification of the second embodiment;

FIG. 16 is a top view illustrating an example of the configuration of the semiconductor device according to the fourth modification of the second embodiment;

FIG. 17 is a cross sectional view illustrating an example of the configuration of a semiconductor device according to a fifth modification of the second embodiment;

FIG. 18 is a cross sectional view illustrating an example of the configuration of a semiconductor device according to a sixth modification of the second embodiment;

FIG. 19 is a cross sectional view illustrating an example of the configuration of a semiconductor device according to a seventh modification of the second embodiment;

FIG. 20 is a cross sectional view illustrating an example of the configuration of a semiconductor device according to an eighth modification of the second embodiment;

FIG. 21 is a cross sectional view illustrating an example of the configuration of a semiconductor device according to a ninth modification of the second embodiment;

FIG. 22 is a cross sectional view illustrating an example of the configuration of a semiconductor device according to a tenth modification of the second embodiment;

FIG. 23 is a cross sectional view illustrating an example of the configuration of a semiconductor device according to an eleventh modification of the second embodiment;

FIG. 24 is a cross sectional view illustrating an example of the configuration of a semiconductor device according to a twelfth modification of the second embodiment;

FIG. 25 is a cross sectional view illustrating an example of the configuration of a semiconductor device according to a thirteenth modification of the second embodiment;

FIG. 26 is a cross sectional view illustrating an example of the configuration of a semiconductor device according to a fourteenth modification of the second embodiment;

FIG. 27 is a cross sectional view illustrating an example of the configuration of a semiconductor device according to a third embodiment;

FIG. 28 is a top view illustrating the example of the configuration of the semiconductor device according to the third embodiment;

FIG. 29 is a cross sectional view illustrating an example of the configuration of a semiconductor device according to a comparative example of the third embodiment;

FIG. 30 is a top view illustrating an example of the configuration of the semiconductor device according to the comparative example of the third embodiment;

FIG. 31 is a cross sectional view illustrating an example of the configuration of a semiconductor device according to a first modification of the third embodiment;

FIG. 32 is a top view illustrating an example of the configuration of the semiconductor device according to the first modification of the third embodiment;

FIG. 33 is a cross sectional view illustrating an example of the configuration of a semiconductor device according to a second modification of the third embodiment;

FIG. 34 is a top view illustrating an example of the configuration of the semiconductor device according to the second modification of the third embodiment;

FIG. 35 is a cross sectional view illustrating an example of the configuration of a semiconductor device according to a third modification of the third embodiment;

FIG. 36 is a top view illustrating an example of the configuration of the semiconductor device according to the third modification of the third embodiment;

FIG. 37 is a top view illustrating an example of the configuration of a semiconductor device according to a fourth modification of the third embodiment;

FIG. 38 is a cross sectional view illustrating an example of the configuration of a semiconductor device according to a fifth modification of the third embodiment; and

FIG. 39 is a top view illustrating an example of the configuration of the semiconductor device according to the fifth modification of the third embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a substrate, a plurality of first semiconductor chips, a plurality of first resins, and a second semiconductor chip. The substrate has a first surface. The plurality of first semiconductor chips are stacked while being displaced in a direction substantially parallel to the first surface. The plurality of first resins are provided on respective lower surfaces of the plurality of first semiconductor chips. The second semiconductor chip is provided on the first surface. At least one of the plurality of first resins is in contact with an upper surface of the second semiconductor chip.

### First Embodiment

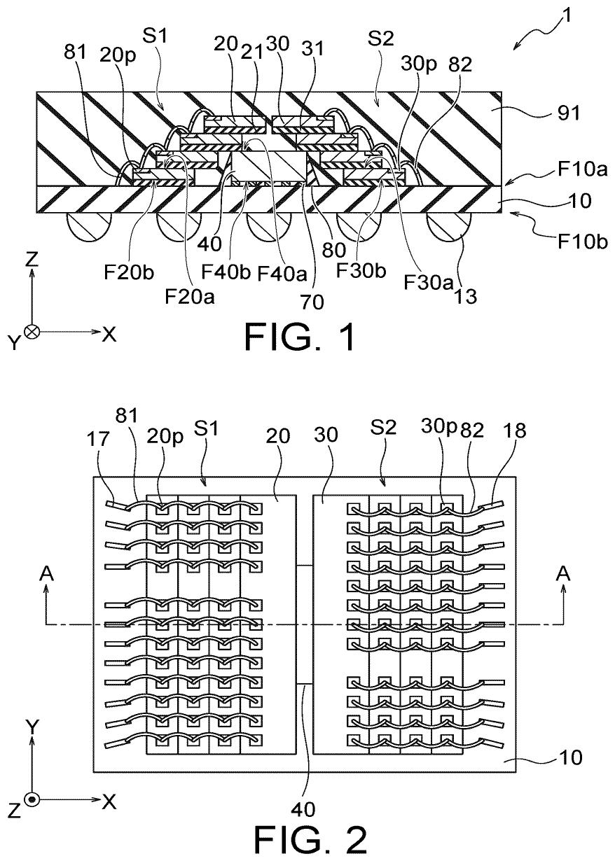

FIG. 1 is a cross sectional view illustrating an example of the configuration of a semiconductor device 1 according to a first embodiment. FIG. 2 is a top view illustrating the example of the configuration of the semiconductor device 1 according to the first embodiment. Line A-A in FIG. 2 indicates a cross section corresponding to the cross sectional view of FIG. 1.

The semiconductor device 1 includes a wiring substrate 10, stacks S1, S2, a semiconductor chip 40, bonding wires 81, 82, and a sealing resin 91. The semiconductor device 1 is, for example, a packaged NAND type flash memory.

Note that FIG. 1 illustrates an X direction and a Y direction parallel to a front surface of a substrate (the wiring substrate 10) and orthogonal to each other, and a Z direction orthogonal to the front surface of the substrate (the wiring substrate 10). In the present specification, the positive Z direction is an upward direction, and the negative Z direction is a downward direction. The negative Z direction may or may not be aligned with the direction of gravity.

The wiring substrate 10 may be a printed circuit board or an interposer including wiring layers (not illustrated) and insulating layers (not illustrated). A low resistance metal such as copper (Cu), nickel (Ni), or alloy thereof is used as the wiring layers. An insulating material such as glass epoxy resin is used as the insulating layers. The wiring substrate 10 may include a multi-layer wiring structure formed by stacking a plurality of wiring layers and a plurality of insulating layers. The wiring substrate 10 may include a penetration electrode penetrating through front and back surfaces thereof like an interposer.

A solder resist layer provided on a wiring layer is provided on the front surface (a surface F10a) of the wiring substrate 10. The solder resist layer is also used for an insulating layer for protecting the wiring layer and for preventing short-circuit defect. Pads 17, 18 (see FIG. 2) are provided on the front surface of the wiring substrate 10. The pads 17, 18 are wiring layers exposed through the solder resist layer. The pad 17 is electrically connected to the stack S1. The pad 18 is electrically connected to the stack S2. The pads 17, 18 are, for example, gold (Au) plated electrodes. A pad (not illustrated) to be connected to a metallic material 70 is also provided on the front surface of the wiring substrate 10.

A solder resist layer provided on a wiring layer is provided on the back surface (a surface F10b) of the wiring substrate 10. Metal bumps 13 are provided on the wiring layer exposed through the solder resist layer. The metal bumps 13 are provided to electrically connect non-illustrated other components to the wiring substrate 10.

The stack S1 has semiconductor chips 20 and bonding layers 21. The bonding layer 21 is, for example, a die attachment film (DAF) or non conductive paste (NCP). The stack S1 is a stack in which the plurality of semiconductor chips 20 are stacked while being displaced in a direction (for example, the positive X direction) orthogonal to a stacked direction (the Z direction). The stack S1 is provided on the surface F10a.

The semiconductor chip 20 is, for example, a memory chip including a NAND type flash memory. The semiconductor chip 20 has a semiconductor element (not illustrated) on its front surface (upper surface, a surface F20a). The semiconductor element may be, for example, a memory cell array and its peripheral circuit (complementary metal oxide semiconductor (CMOS) circuit). The memory cell array may be a stereoscopic memory cell array in which a plurality of memory cells are three-dimensionally disposed. In FIG. 1, the semiconductor chips 20 as four memory chips are stacked. However, the number of stacked semiconductor chips may be three or less or five or more.

The stack S2 has semiconductor chips 30 and bonding layers 31. The bonding layer 31 is, for example, a die attachment film (DAF) or non conductive paste (NCP). The stack S2 is a stack in which the plurality of semiconductor chips 30 are stacked while being displaced in a direction (for example, the negative X direction) orthogonal to the stacked direction (the Z direction). The stack S2 is provided at a position in the X direction substantially parallel to the surface F10a with respect to the position of the stack S1 on the surface F10a.

The semiconductor chip 30 is, for example, a memory chip including a NAND type flash memory. The semiconductor chip 30 has a semiconductor element (not illustrated) on its front surface (upper surface, a surface F30a). The semiconductor element may be, for example, a memory cell array and its peripheral circuit (CMOS circuit). The memory cell array may be a stereoscopic memory cell array in which a plurality of memory cells are three-dimensionally disposed. In FIG. 1, the semiconductor chips 30 as four memory chips are stacked. However, the number of stacked semiconductor chips may be three or less or five or more.

The semiconductor chip 40 is, for example, a controller chip that controls a memory chip. A non-illustrated semiconductor element is provided on a surface F40b of the semiconductor chip 40 facing the wiring substrate 10. The semiconductor element may be, for example, a complementary metal oxide semiconductor (CMOS) circuit constituting a controller. An electrode pillar (not illustrated) electrically connected to the semiconductor element is provided on the surface F40b which is a back surface (lower surface) of the semiconductor chip 40. A low resistance metallic material such as copper, nickel, or alloy thereof is used as the electrode pillar.

The semiconductor chip 40 is provided on the surface F10a. The semiconductor chip 40 is provided between the stacks S1 and S2, for example.

The metallic material 70 is provided around the electrode pillar as a connection bump. The electrode pillar is electrically connected through the metallic material 70 to the wiring layer exposed at an opening part of the solder resist layer. A low resistance metallic material such as solder, silver, or copper is used as the metallic material 70. The metallic material 70 electrically connects the electrode pillar of the semiconductor chip 40 and the wiring layer of the wiring substrate 10.

A resin layer 80 is provided in a region around the metallic material 70 and a region between the semiconductor chip 40 and the wiring substrate 10. The resin layer 80 is, for example, cured underfill resin and covers and protects the circumference of the semiconductor chip 40.

The bonding wire 81 is connected to the wiring substrate 10 and optional electrode pads of the semiconductor chips 20. The bonding wire 82 is connected to the wiring substrate 10 and optional pads of the semiconductor chips 30. The bonding wires 81, 82 are, for example, gold (Au) wires. For the connection through the bonding wires 81, 82, the semiconductor chips 20, 30 are stacked while being displaced as corresponding to pads 20p, 30p.

The sealing resin 91 seals the stacks S1, S2, the semiconductor chip 40, the bonding wires 81, 82, and the like. Accordingly, in the semiconductor device 1, the stacks S1, S2 and the semiconductor chip 40 are constituted as one semiconductor package on the wiring substrate 10.

Details of the configuration of the stacks S1, S2 and the semiconductor chip 40 will be described below.

As illustrated in FIG. 2, the semiconductor chip 20 is disposed such that its short sides are substantially parallel to the X direction and its long sides are substantially parallel to the Y direction. Accordingly, the plurality of semiconductor chips 20 are stacked while being displaced in the short side direction of the semiconductor chips 20. The semiconductor chip 20 has an elongated shape when viewed from above.

As illustrated in FIG. 1, at least one semiconductor chip 20 among the stacked semiconductor chips 20 is disposed so as to extend over the semiconductor chips 20 and the semiconductor chip 40. In the example illustrated in FIG. 1, the semiconductor chip 20 in the third stage is disposed so as to extend over the semiconductor chip 20 in the second stage and the semiconductor chip 40. Specifically, the semiconductor chip 20 in the third stage is in contact with the semiconductor chip 20 in the second stage and the semiconductor chip 40 through the bonding layer 21. Accordingly, the semiconductor chip 20 in the third stage is supported by the semiconductor chip 40. The height of the surface F20a of the semiconductor chip 20 in the second stage is substantially the same as the height of the surface F40a of the semiconductor chip 40.

Alternatively, the height of the surface F20a of the semiconductor chip 20 in the second stage may be slightly smaller than the height of the surface F40a of the semiconductor chip 40. The height of the surface F20a of the semiconductor chip 20 in the second stage may be slightly greater than the height of the surface F40a of the semiconductor chip 40. Even at such a time, the bonding layer 21 of the semiconductor chip 20 in the third stage can absorb the level difference. Even if the level difference differs by more than or equal to 1 μm and less than 5 μm, the difference in level difference can be absorbed by the bonding layer 21. Even if the level difference differs by more than or equal to 5 μm and less than 10 μm, the difference in level difference can be absorbed by the bonding layer 21. Even if the level difference differs by more than or equal to 10 μm and less than 20 μm, the difference in level difference can be absorbed by the bonding layer 21. As described, if the difference in level difference can be absorbed by the bonding layer 21, the height of the surface F20a of the semiconductor chip 20 in the second stage may be substantially the same as the height of the surface F40a of the semiconductor chip 40.

The bonding layer 21 provided at the lower part of the semiconductor chip 20 in the third stage may be thicker than the bonding layers 21 provided at the lower parts of the other semiconductor chips 20. Accordingly, it is possible to make it easier to absorb the level difference between the surface F20a of the semiconductor chip 20 in the second stage and the surface F40a. As a result, the semiconductor chip 20 in the third stage can be more appropriately mounted on the semiconductor chip 20 in the second stage and the semiconductor chip 40.

As illustrated in FIG. 2, the semiconductor chip 30 is disposed such that its short sides are substantially parallel to the X direction and its long sides are substantially parallel to the Y direction. Accordingly, the plurality of semiconductor chips 30 are stacked while being displaced in the short side direction of the semiconductor chips 30. The semiconductor chip 30 has an elongated shape when viewed from above.

As illustrated in FIG. 1, at least one semiconductor chip 30 among the stacked semiconductor chips 30 is disposed so as to extend over the semiconductor chips 30 and the semiconductor chip 40. In the example illustrated in FIG. 1, the semiconductor chip 30 in the third stage is disposed so as to extend over the semiconductor chip 30 in the second stage and the semiconductor chip 40. Specifically, the semiconductor chip 30 in the third stage is in contact with the semiconductor chip 30 in the second stage and the semiconductor chip 40 through the bonding layer 31.

Accordingly, the semiconductor chip 30 in the third stage is supported by the semiconductor chip 40. The height of the surface F30a of the semiconductor chip 30 in the second stage is substantially the same as the height of the surface F40a of the semiconductor chip 40.

The bonding layer 31 provided at the lower part of the semiconductor chip 30 in the third stage may be thicker than the bonding layers 31 provided at the lower parts of the other semiconductor chips 30. Accordingly, it is possible to make it easier to absorb the level difference between the surface F30a of the semiconductor chip 30 in the third stage and the surface F40a. As a result, the semiconductor chip 30 in the third stage can be more appropriately mounted on the semiconductor chip 30 in the second stage and the semiconductor chip 40.

As described above, according to the first embodiment, at least one of the semiconductor chips 20 is disposed so as to extend over the semiconductor chips 20 and the semiconductor chip 40. At least one of the semiconductor chips 30 is disposed so as to extend over the semiconductor chips 30 and the semiconductor chip 40. Accordingly, the stacks S1, S2 are supported by the semiconductor chip 40. As a result, it is possible to make it easier to stack the semiconductor chips 20, 30 in higher stages. Accordingly, the semiconductor chips 20, 30 can be more appropriately disposed in the package.

As illustrated in FIG. 2, the semiconductor chips 20, 30 whose ratio (aspect ratio) of the width of the long sides to the width of the short sides is high are used in some cases. As will be described later, even in the case where the semiconductor chips 20, 30 having a high aspect ratio are used, it is possible to make it easier to stack the semiconductor chips 20, 30 in higher stages. Note that the aspect ratio of the semiconductor chips 20, 30 illustrated in FIG. 2 is an example.

The ratio (aspect ratio) of the width of the long sides to the width of the short sides of the semiconductor chips 20, 30 is more than or equal to a predetermined value. The predetermined value is three, for example. For example, as the width of the short sides decreases, the aspect ratio increases. The predetermined value may be five or ten, for example.

Note that in the first embodiment, the amount of displacement (offset amount) of the stacks S1, S2 is less than one half of the width of the short sides (in the X direction) of the semiconductor chips 20, 30. Specifically, the semiconductor chips 20, 30 are stacked while being displaced in the X direction by less than one half of the length of the short sides of the semiconductor chips 20, 30. The amount of displacement indicates a distance of displacement in the X direction between certain ones of the semiconductor chips 20, 30 and the semiconductor chips 20, 30 vertically adjacent thereto, the displacement being formed for exposing the pads 20p, 30p.

In the first embodiment, the semiconductor chips 20, 30 in the third stages are disposed so as to extend over the semiconductor chip 40. However, the semiconductor chips 20, 30 in the fourth or higher stages may be disposed so as to extend over the semiconductor chip 40.

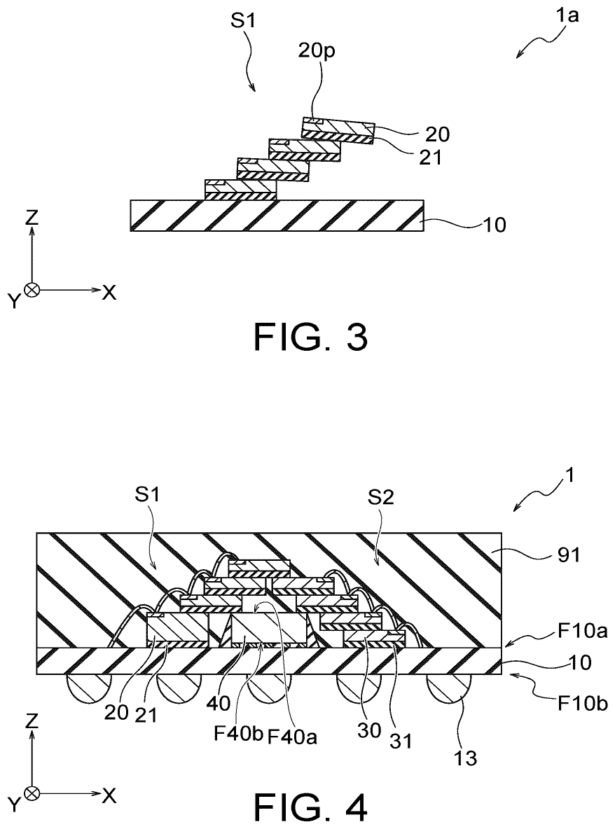

FIG. 3 is a cross sectional view illustrating an example of the configuration of a semiconductor device 1a according to a comparative example of the first embodiment. The comparative example of the first embodiment is different from the first embodiment in that the semiconductor chip 20 is not disposed so as to extend over the semiconductor chip 40. Note that since the stack S1 will be described in detail with reference to FIG. 3, illustration of the configuration excluding the wiring substrate 10 and the stack S1 in FIG. 1 is omitted.

As the width of the short sides (in the X direction) of the semiconductor chip 20 decreases, that is, as the aspect ratio increases, the semiconductor chips 20 in high stages are likely to be easily inclined with respect to the wiring substrate 10. This is because the area in which the lower semiconductor chips 20 support the upper semiconductor chips 20 decreases when the semiconductor chips 20 are die-bonded. As a result, it is difficult to stack the semiconductor chips 20 in high stages.

In contrast, in the first embodiment, the semiconductor chips 20, 30 are disposed so as to extend over the semiconductor chip 40 and are supported by the semiconductor chip 40. Accordingly, even in the case where the semiconductor chips 20, 30 having a high aspect ratio are used, the semiconductor chips 20, 30 can be stacked in higher stages. First modification of first embodiment

FIG. 4 is a cross sectional view illustrating an example of the configuration of the semiconductor device 1 according to a first modification of the first embodiment. The first modification of the first embodiment is different from the first embodiment in that the number of stages of the semiconductor chips 20, 30 that extend over the semiconductor chip 40 is different between the stacks S1, S2.

In the example illustrated in FIG. 4, the semiconductor chip 20 in the lowest stage is thicker than the other semiconductor chips 20. The height of the surface F20a of the semiconductor chip 20 in the lowest stage is substantially the same as the height of the surface F40a of the semiconductor chip 40. Accordingly, the semiconductor chip 20 in the second stage is disposed so as to extend over the semiconductor chip 20 in the lowest stage and the semiconductor chip 40.

The semiconductor chip 20 in the fourth stage of the stack S1 is disposed so as to be overlapped on at least part of the semiconductor chip 30 in the fourth stage of the stack S2 when viewed in the Z direction. Accordingly, the package area can be made smaller.

As in the first modification of the first embodiment, the number of stages of the semiconductor chips 20, 30 that extend over the semiconductor chip 40 may be different between the stacks S1, S2. With the semiconductor device 1 according to the first modification of the first embodiment, it is possible to obtain the same effects as in the first embodiment.

### Second Modification of First Embodiment

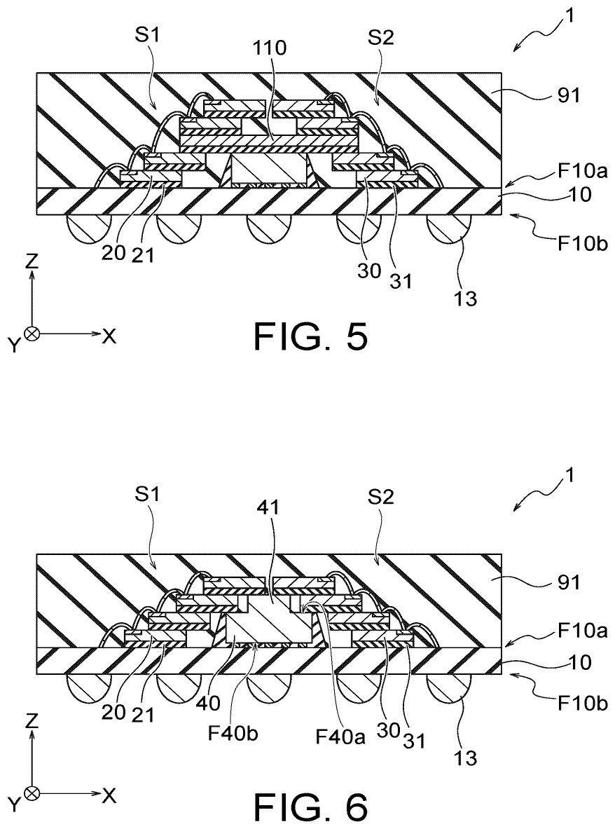

FIG. 5 is a cross sectional view illustrating an example of the configuration of the semiconductor device 1 according to a second modification of the first embodiment. The second modification of the first embodiment is different from the first embodiment in that a spacer 110 is provided.

The semiconductor device 1 further includes the spacer 110. The spacer 110 is provided between the semiconductor chips 20, 30 in the second stages and the semiconductor chips 20, 30 in the third stages. The spacer 110 is disposed so as to extend over the semiconductor chips 20, 30 in the second stages and the semiconductor chip 40. The spacer 110 may include Si or may include resin such as polyimide (PI), for example.

As in the second modification of the first embodiment, the spacer 110 may be provided. With the semiconductor device 1 according to the second modification of the first embodiment, it is possible to obtain the same effects as in the first embodiment.

### Third Modification of First Embodiment

FIG. 6 is a cross sectional view illustrating an example of the configuration of the semiconductor device 1 according to a third modification of the first embodiment. The third modification of the first embodiment is different from the first embodiment in that part of the surface F40a of the semiconductor chip 40 protrudes upwardly.

The semiconductor chip 40 further includes a protrusion 41 provided on part of the surface F40a and protruding upwardly. The height of the protrusion 41 is substantially the same as the thickness of the semiconductor chips 20, 30 in the third stages. The semiconductor chip 20 in the fourth stage is disposed so as to extend over the semiconductor chip 20 in the third stage and the protrusion 41 of the semiconductor chip 40. The semiconductor chip 30 in the fourth stage is disposed so as to extend over the semiconductor chip 30 in the third stage and the protrusion 41 of the semiconductor chip 40. Accordingly, the semiconductor chip 40 can support the semiconductor chips 20, 30 in the third and fourth stages. As a result, it is possible to make it easier to stack the semiconductor chips 20, 30 in higher stages.

The protrusion 41 is formed by cutting the circumference of the protrusion 41 like a step using a grinder that grinds the surface F40a of the semiconductor chip 40, for example.

As in the third modification of the first embodiment, part of the surface F40a of the semiconductor chip 40 may protrude upwardly. With the semiconductor device 1 according to the third modification of the first embodiment, it is possible to obtain the same effects as in the first embodiment.

### Fourth Modification of First Embodiment

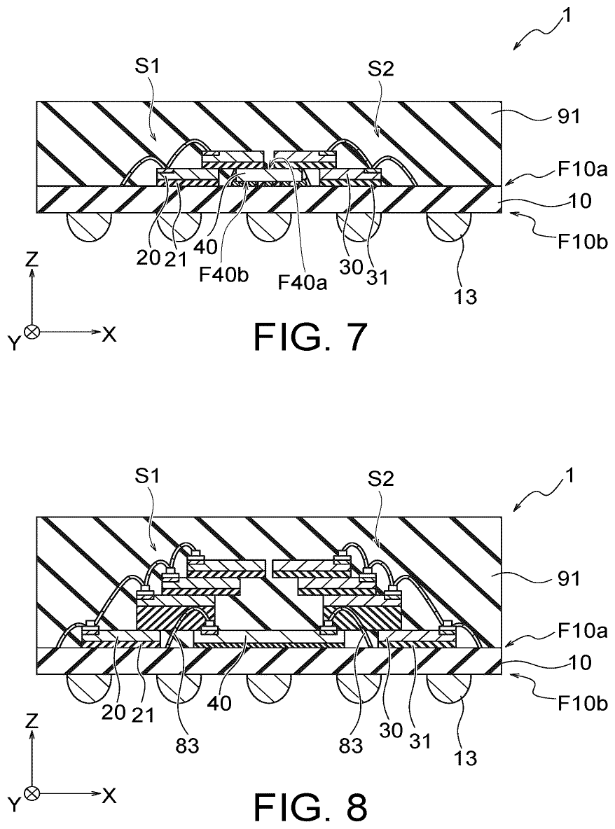

FIG. 7 is a cross sectional view illustrating an example of the configuration of the semiconductor device 1 according to a fourth modification of the first embodiment. The fourth modification of the first embodiment is different from the first embodiment in that the semiconductor chips 20, 30 in the second stages are disposed so as to extend over the semiconductor chip 40.

The semiconductor chips 20, 30 in the second stages are disposed so as to extend over the semiconductor chips 20, 30 in the lowest stages and the semiconductor chip 40. The height of the surfaces F20a, F30a of the semiconductor chips 20, 30 in the lowest stages is substantially the same as the height of the surface F40a of the semiconductor chip 40.

The amount of displacement (offset amount) of the stacks S1, S2 is more than or equal to one half of the width of the short sides (in the X direction) of the semiconductor chips 20, 30. Specifically, the semiconductor chips 20, 30 are stacked while being displaced in the X direction by more than or equal to one half of the length of the short sides of the semiconductor chips 20, 30.

As in the fourth modification of the first embodiment, the semiconductor chips 20, 30 in the second stages may be disposed so as to extend over the semiconductor chip 40. With the semiconductor device 1 according to the fourth modification of the first embodiment, it is possible to obtain the same effects as in the first embodiment.

### Fifth Modification of First Embodiment

FIG. 8 is a cross sectional view illustrating an example of the configuration of the semiconductor device 1 according to a fifth modification of the first embodiment. The fifth modification of the first embodiment is different from the first embodiment in that the semiconductor chip 40 is connected to the wiring substrate 10 by wire bonding.

The semiconductor chip 20 in the third stage is disposed so as to extend over the semiconductor chip 20 in the second stage and the semiconductor chip 40. The semiconductor chip 30 in the third stage is disposed so as to extend over the semiconductor chip 30 in the second stage and the semiconductor chip 40. The height of the surfaces F20a, F30a of the semiconductor chips 20, 30 in the lowest stages is substantially the same as the height of the surface F40a of the semiconductor chip 40.

The semiconductor device 1 further includes bonding wires 83. The bonding wire 83 electrically connects the wiring substrate 10 and the semiconductor chip 40. At least portions (for example, loop top portions) of the bonding wires 83 are buried in the bonding layers 21, 31 provided at the lower parts of the semiconductor chips 20, 30 in the second stages.

The bonding layer 21 provided at the lower part of the semiconductor chip 20 in the third stage is thicker than the bonding layers 21 provided at the lower parts of the other semiconductor chips 20. The bonding layer 31 provided at the lower part of the semiconductor chip 30 in the third stage is thicker than the bonding layers 31 provided at the lower parts of the other semiconductor chips 30.

As in the fifth modification of the first embodiment, the semiconductor chip 40 may be connected to the wiring substrate 10 by wire bonding. With the semiconductor device 1 according to the fifth modification of the first embodiment, it is possible to obtain the same effects as in the first embodiment.

### Sixth Modification of First Embodiment

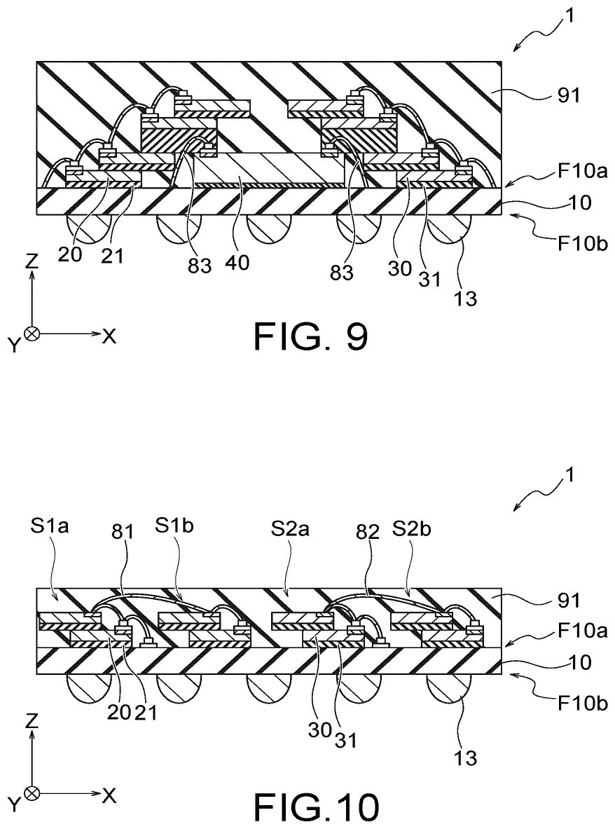

FIG. 9 is a cross sectional view illustrating an example of the configuration of the semiconductor device 1 according to a sixth modification of the first embodiment. The sixth modification of the first embodiment is different from the fifth modification of the first embodiment in that the semiconductor chip 40 is thicker than the semiconductor chips 20, 30.

The semiconductor chip 40 is thicker than the semiconductor chips 20, 30.

The semiconductor chip 20 in the third stage is disposed so as to extend over the semiconductor chip 20 in the second stage and the semiconductor chip 40. The semiconductor chip 30 in the third stage is disposed so as to extend over the semiconductor chip 30 in the second stage and the semiconductor chip 40. The height of the surfaces F20a, F30a of the semiconductor chips 20, 30 in the second stages is substantially the same as the height of the surface F40a of the semiconductor chip 40.

Note that not only the semiconductor chips 20, 30 in the third stages but also the semiconductor chips 20, 30 in the fourth or higher stages may be disposed so as to extend over the immediately underlying semiconductor chips 20, 30 and the semiconductor chip 40.

As in the sixth modification of the first embodiment, the semiconductor chip 40 may be thicker than the semiconductor chips 20, 30. With the semiconductor device 1 according to the sixth modification of the first embodiment, it is possible to obtain the same effects as in the fifth modification of the first embodiment.

### Second Embodiment

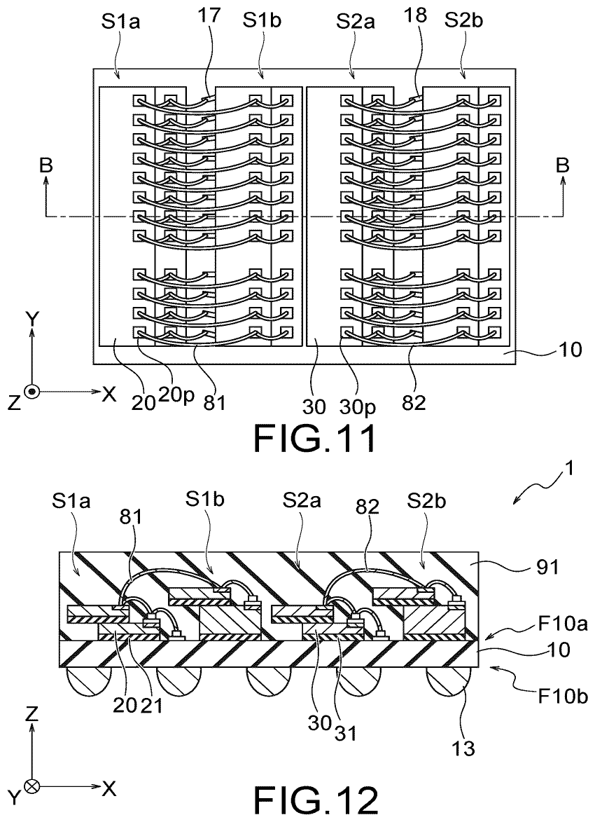

FIG. 10 is a cross sectional view illustrating an example of the configuration of the semiconductor device 1 according to a second embodiment. FIG. 11 is a top view illustrating the example of the configuration of the semiconductor device 1 according to the second embodiment. Line B-B in FIG. 11 indicates a cross section corresponding to the cross sectional view of FIG. 10.

The semiconductor device 1 includes stacks S1a, S1b, S2a, and S2b.

As illustrated in FIG. 11, the stacks Sla, S1b are disposed to be aligned in the short side direction of the semiconductor chips 20. The stacks S2a, S2b are disposed to be aligned in the short side direction of the semiconductor chips 30.

In the example illustrated in FIG. 10, the orientations (displacement directions) of the stacks S1a, S1b, S2a, and S2b, that is, the orientations of the semiconductor chips 20, 30 are all the same.

Each of the stacks Sla, S1b has the semiconductor chips 20 stacked in two stages. The semiconductor chips 20 in the lowest stages of the stacks S1a, S1b are provided at different positions on the surface F10a. Note that the number of the stacked semiconductor chips 20 may be three or more.

The plurality of bonding wires 81 electrically connect the plurality of semiconductor chips 20 to one another. The stacks S1a, S1b are electrically connected to each other through the bonding wires 81. The bonding wires 81 unicursally connect the plurality of semiconductor chips 20 to one another, for example.

Each of the stacks S2a, S2b has the semiconductor chips 30 stacked in two stages. The semiconductor chips 30 in the lowest stages of the stacks S2a, S2b are provided at different positions on the surface F10a. Note that the number of the stacked semiconductor chips 30 may be three or more.

The plurality of bonding wires 82 electrically connect the plurality of semiconductor chips 30 to one another. The stacks S2a, S2b are electrically connected to each other through the bonding wires 82. The bonding wires 82 unicursally connect the plurality of semiconductor chips 30 to one another, for example.

As described above, according to the second embodiment, the plurality of stacks S1a, S1b are electrically connected to each other through the bonding wire 81. The plurality of stacks S2a, S2b are electrically connected to each other through the bonding wire 82. Accordingly, multi-stage stacking is not performed, and a plurality of stacks which are electrically connected and are relatively low layers are provided.

As illustrated in FIG. 11, the semiconductor chips 20, 30 having a relatively high aspect ratio are used in some cases. As described with reference to FIG. 3, multi-stage stacking of the semiconductor chips 20, 30 having a relatively high aspect ratio is difficult in some cases.

In contrast, in the second embodiment, the stacks S1a, S1b, S2a, and S2b which are relatively low layers are disposed to be aligned in the short side direction of the semiconductor chips 20, 30. Accordingly, even in the case where the semiconductor chips 20, 30 having a high aspect ratio are used, the semiconductor chips 20, 30 can be more appropriately disposed. Accordingly, the semiconductor chips 20, 30 can be more appropriately disposed in the package.

Since the stacks S1a, S1b, S2a, and S2b are relatively low layers, it is not necessary to cut the semiconductor chips 20, 30 thin, and the semiconductor chips 20, 30 can be made thicker. Accordingly, pick-up characteristics are improved, and chip breakage during pick-up or the like can be reduced.

### First Modification of Second Embodiment

FIG. 12 is a cross sectional view illustrating an example of the configuration of the semiconductor device 1 according to a first modification of the second embodiment. The first modification of the second embodiment is different from the second embodiment in that some of the semiconductor chips 20, 30 are thick.

The semiconductor chip 20 in the lower stage of the stack S1b is thicker than the other semiconductor chip 20. The semiconductor chip 20 in the upper stage of the stack S1b is disposed so as to be overlapped on at least part of the bonding wire 81 that connects the wiring substrate 10 and the semiconductor chip 20 in the lower stage of the stack Sla when viewed in the Z direction. Accordingly, the package area can be made smaller.

Similarly, the semiconductor chip 30 in the lower stage of the stack S2b is thicker than the other semiconductor chip 30.

Note that a spacer may be provided between the wiring substrate 10 and the stacks S1b, S2b without the thick semiconductor chips 20, 30 being provided.

As in the first modification of the second embodiment, some of the semiconductor chips 20, 30 may be thick. With the semiconductor device 1 according to the first modification of the second embodiment, it is possible to obtain the same effects as in the second embodiment.

### Second Modification of Second Embodiment

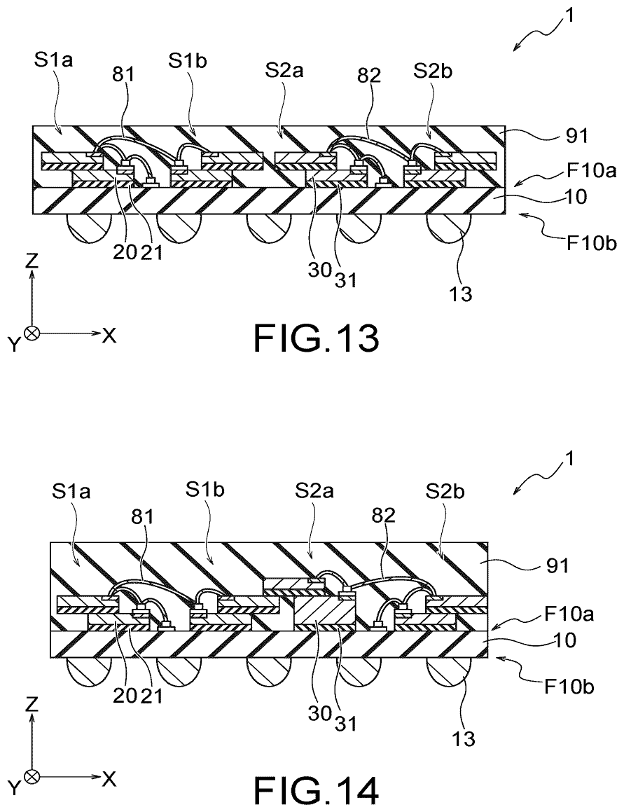

FIG. 13 is a cross sectional view illustrating an example of the configuration of the semiconductor device 1 according to a second modification of the second embodiment. The second modification of the second embodiment is different from the second embodiment in that some of the stacks are disposed in a different orientation.

In the example illustrated in FIG. 13, the orientations (displacement directions) of adjacent ones of the stacks S1a, S1b, S2a, and S2b are opposite to each other.

As in the second modification of the second embodiment, some of the stacks may be disposed in a different orientation. With the semiconductor device 1 according to the second modification of the second embodiment, it is possible to obtain the same effects as in the second embodiment.

### Third Modification of Second Embodiment

FIG. 14 is a cross sectional view illustrating an example of the configuration of the semiconductor device 1 according to a third modification of the second embodiment. The third modification of the second embodiment is different from the second modification of the second embodiment in that some of the semiconductor chips 20, 30 are thick. Specifically, the third modification of the second embodiment is also a combination of the first and second modifications of the second embodiment.

The semiconductor chip 30 in the lower stage of the stack S2a is thicker than the other semiconductor chip 30. The semiconductor chip 30 in the upper stage of the stack S2a is disposed so as to be overlapped on at least part of the semiconductor chip 20 in the upper stage of the stack S1b when viewed in the Z direction. Accordingly, the package area can be made smaller.

Note that connection of the bonding wire 82 illustrated in FIG. 14 is partially different from connection of the bonding wire 82 illustrated in FIG. 13. The bonding wire 82 connected to the wiring substrate 10 is connected to the semiconductor chip 30 in the lower stage of the stack S2b.

As in the third modification of the second embodiment, some of the semiconductor chips 20, 30 may be thick. With the semiconductor device 1 according to the third modification of the second embodiment, it is possible to obtain the same effects as in the second modification of the second embodiment.

### Fourth Modification of Second Embodiment

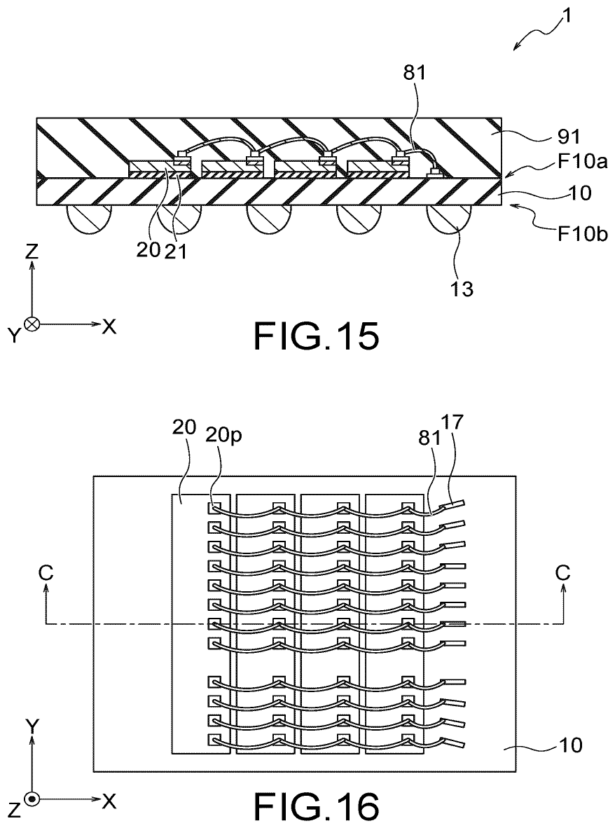

FIG. 15 is a cross sectional view illustrating an example of the configuration of the semiconductor device 1 according to a fourth modification of the second embodiment. FIG. 16 is a top view illustrating an example of the configuration of the semiconductor device 1 according to the fourth modification of the second embodiment. Line C-C in FIG. 16 indicates a cross section corresponding to the cross sectional view of FIG. 15. The fourth modification of the second embodiment is different from the second embodiment in that three or more of the semiconductor chips 20 electrically connected are provided to be in contact with the wiring substrate 10.

Note that in the example illustrated in FIGS. 15 and 16, the semiconductor chips 30 are not illustrated.

Three or more of the semiconductor chips 20 electrically connected to one another through the bonding wire 81 are bonded to the surface F10a of the wiring substrate 10 through the bonding layers 21. In the example illustrated in FIG. 15, the four semiconductor chips 20 are bonded to the surface F10a of the wiring substrate 10 through the bonding layers 21. Accordingly, the semiconductor chips 20 may not be stacked.

As in the fourth modification of the second embodiment, the three or more semiconductor chips 20 electrically connected may be provided to be in contact with the wiring substrate 10. With the semiconductor device 1 according to the fourth modification of the second embodiment, it is possible to obtain the same effects as in the second embodiment.

### Fifth Modification of Second Embodiment

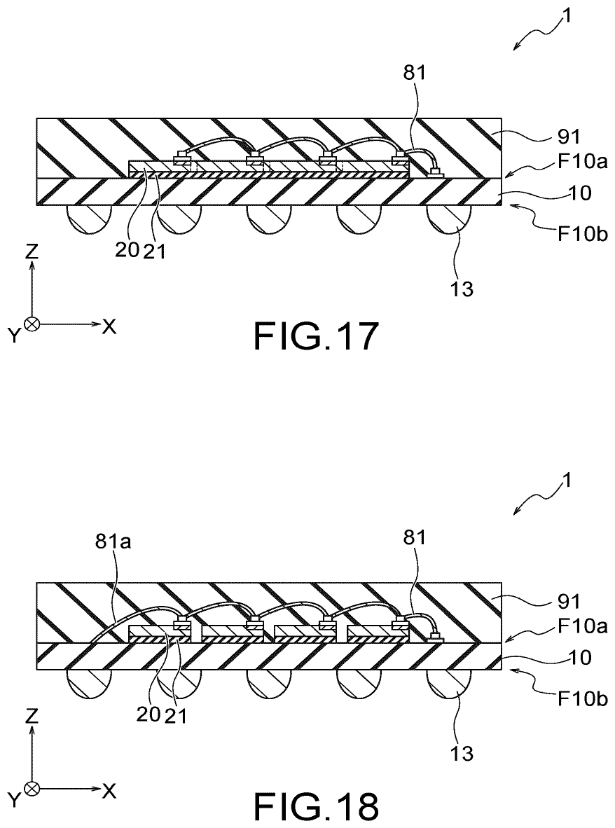

FIG. 17 is a cross sectional view illustrating an example of the configuration of the semiconductor device 1 according to a fifth modification of the second embodiment. The fifth modification of the second embodiment is different from the fourth modification of the second embodiment in that the semiconductor chips 20 are not diced (singulated).

Since the semiconductor chips 20 are not diced, the four semiconductor chips 20 are cut out from a wafer while being connected and are mounted on the wiring substrate 10. Accordingly, the process can further be simplified.

As in the fifth modification of the second embodiment, the semiconductor chips 20 may not be diced (singulated). With the semiconductor device 1 according to the fifth modification of the second embodiment, it is possible to obtain the same effects as in the fourth modification of the second embodiment.

### Sixth Modification of Second Embodiment

FIG. 18 is a cross sectional view illustrating an example of the configuration of the semiconductor device 1 according to a sixth modification of the second embodiment. The sixth modification of the second embodiment is different from the fourth modification of the second embodiment in that supply of power/ground is additionally performed. The semiconductor device 1 further includes a bonding wire 81a that electrically connects the leftmost semiconductor chip 20 in FIG. 18 and the wiring substrate 10. The leftmost semiconductor chip 20 in FIG. 18 is supplied with a reference voltage (power/ground) from the bonding wire 81a.

The rightmost semiconductor chip 20 in FIG. 18 is supplied with a signal and the reference voltage (power/ground) from the wiring substrate 10 through the bonding wire 81. The leftmost semiconductor chip 20 is distant from a connection point between the rightmost semiconductor chip 20 and the wiring substrate 10. By providing the bonding wire 81a capable of supplying the reference voltage, the power supply can be enhanced.

As in the sixth modification of the second embodiment, supply of power/ground may be additionally performed. With the semiconductor device 1 according to the sixth modification of the second embodiment, it is possible to obtain the same effects as in the fourth modification of the second embodiment.

### Seventh Modification of Second Embodiment

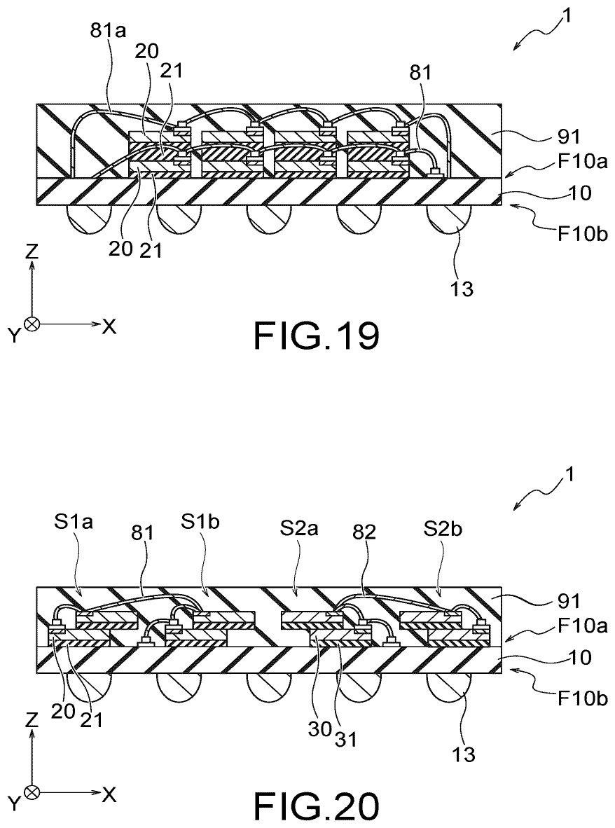

FIG. 19 is a cross sectional view illustrating an example of the configuration of the semiconductor device 1 according to a seventh modification of the second embodiment. The seventh modification of the second embodiment is different from the fourth modification of the second embodiment in that stacking of the semiconductor chips 20 is performed.

Note that the bonding wire 81a described in the sixth modification of the second embodiment is illustrated in FIG. 19. However, the bonding wire 81a may not be provided.

The semiconductor device 1 is provided with the semiconductor chips 20 stacked on the semiconductor chips 20 in contact with the wiring substrate 10. The bonding wire 81 connected to the semiconductor chips 20 in the lower stage is buried in the bonding layers 21 provided at the lower parts of the semiconductor chips 20 in the upper stage.

As in the seventh modification of the second embodiment, stacking of the semiconductor chips 20 may be performed. With the semiconductor device 1 according to the seventh modification of the second embodiment, it is possible to obtain the same effects as in the fourth modification of the second embodiment.

### Eighth Modification of Second Embodiment

FIG. 20 is a cross sectional view illustrating an example of the configuration of the semiconductor device 1 according to an eighth modification of the second embodiment. The eighth modification of the second embodiment is different from the second embodiment in that some of the stacks are disposed in a different orientation.

In the example illustrated in FIG. 20, the stacks Sla, S1b are disposed in the same orientation and in the opposite orientation to the orientation of the stacks S2a, S2b. The semiconductor chips 20 of the stacks S1a, S1b are stacked while being displaced in the positive X direction. The semiconductor chips 20 of the stacks S2a, S2b are stacked while being displaced in the negative X direction.

As in the eighth modification of the second embodiment, some of the stacks may be disposed in a different orientation. With the semiconductor device 1 according to the eighth modification of the second embodiment, it is possible to obtain the same effects as in the second embodiment.

### Ninth Modification of Second Embodiment

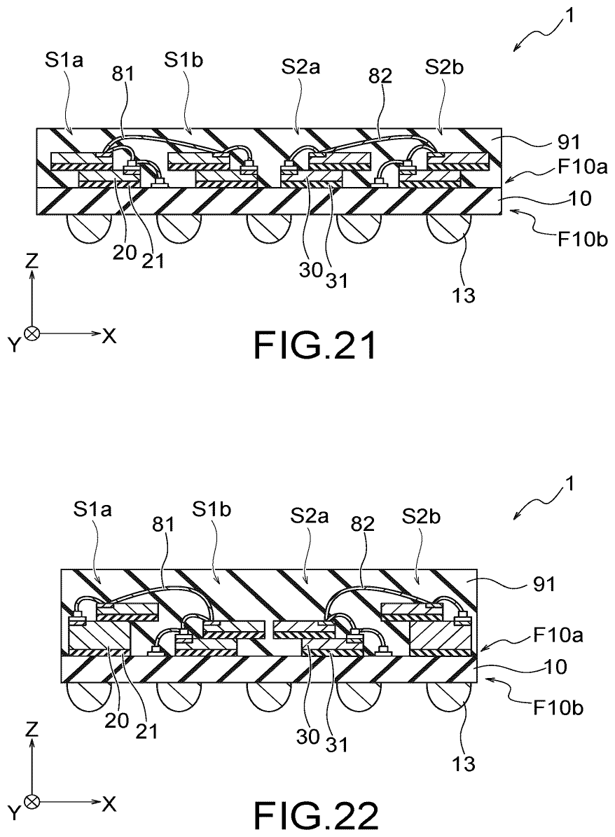

FIG. 21 is a cross sectional view illustrating an example of the configuration of the semiconductor device 1 according to a ninth modification of the second embodiment. The ninth modification of the second embodiment is different from the second embodiment in that some of the stacks are disposed in a different orientation.

In the example illustrated in FIG. 21, the stacks Sla, S1b are disposed in the same orientation and in the opposite orientation to the orientation of the stacks S2a, S2b. The semiconductor chips 20 of the stacks Sla, S1b are stacked while being displaced in the negative X direction. The semiconductor chips 20 of the stacks S2a, S2b are stacked while being displaced in the positive X direction.

As in the ninth modification of the second embodiment, some of the stacks may be disposed in a different orientation. With the semiconductor device 1 according to the ninth modification of the second embodiment, it is possible to obtain the same effects as in the second embodiment.

### Tenth Modification of Second Embodiment

FIG. 22 is a cross sectional view illustrating an example of the configuration of the semiconductor device 1 according to a tenth modification of the second embodiment. The tenth modification of the second embodiment is different from the eighth modification of the second embodiment in that some of the semiconductor chips 20, 30 are thick.

The semiconductor chip 20 in the lower stage of the stack Sla is thicker than the other semiconductor chip 20. The semiconductor chip 20 in the upper stage of the stack Sla is disposed so as to be overlapped on at least part of the bonding wire 81 that connects the wiring substrate 10 and the semiconductor chip 20 in the lower stage of the stack S1b when viewed in the Z direction. Accordingly, the package area can be made smaller.

Similarly, the semiconductor chip 30 in the lower stage of the stack S2b is thicker than the other semiconductor chip 30.

Note that the semiconductor chip 40 may be provided between the semiconductor chip 20 in the lower stage of the stack S1b and the semiconductor chip 30 in the lower stage of the stack S2a.

As in the tenth modification of the second embodiment, some of the semiconductor chips 20, 30 may be thick. With the semiconductor device 1 according to the tenth modification of the second embodiment, it is possible to obtain the same effects as in the eighth modification of the second embodiment.

### Eleventh Modification of Second Embodiment

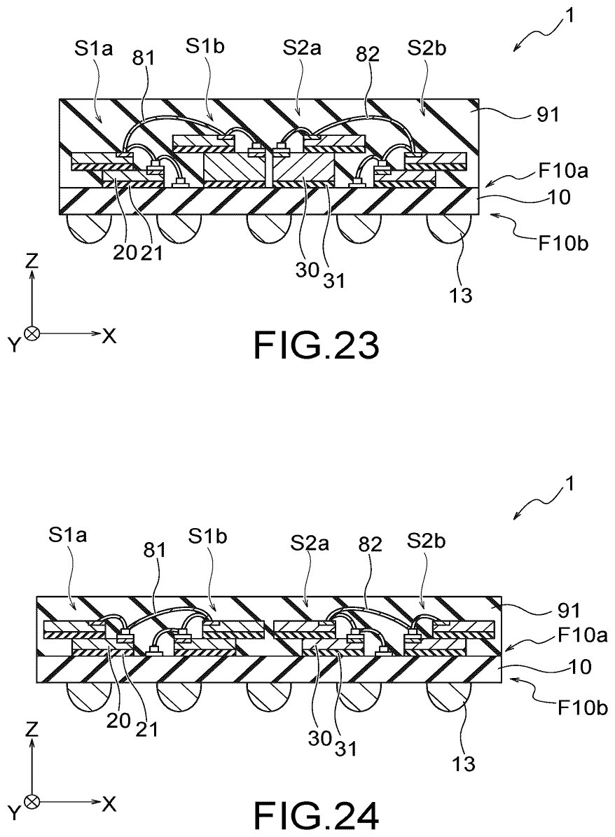

FIG. 23 is a cross sectional view illustrating an example of the configuration of the semiconductor device 1 according to an eleventh modification of the second embodiment. The eleventh modification of the second embodiment is different from the ninth modification of the second embodiment in that some of the semiconductor chips 20, 30 are thick.

The semiconductor chip 20 in the lower stage of the stack S1b is thicker than the other semiconductor chip 20. The semiconductor chip 20 in the upper stage of the stack S1b is disposed so as to be overlapped on at least part of the bonding wire 81 that connects the wiring substrate 10 and the semiconductor chip 20 in the lower stage of the stack Sla when viewed in the Z direction. Accordingly, the package area can be made smaller.

Similarly, the semiconductor chip 30 in the lower stage of the stack S2a is thicker than the other semiconductor chip 30.

As in the eleventh modification of the second embodiment, some of the semiconductor chips 20, 30 may be thick. With the semiconductor device 1 according to the eleventh modification of the second embodiment, it is possible to obtain the same effects as in the ninth modification of the second embodiment.

### Twelfth Modification of Second Embodiment

FIG. 24 is a cross sectional view illustrating an example of the configuration of the semiconductor device 1 according to a twelfth modification of the second embodiment. The twelfth modification of the second embodiment is different from the second modification of the second embodiment in that connection of the bonding wire 81 is different.

In the example illustrated in FIG. 24, the bonding wire 81 connected to the wiring substrate 10 is connected to the semiconductor chip 20 in the lower stage of the stack S1b.

As in the twelfth modification of the second embodiment, connection of the bonding wire 81 may be different. With the semiconductor device 1 according to the twelfth modification of the second embodiment, it is possible to obtain the same effects as in the second modification of the second embodiment.

### Thirteenth Modification of Second Embodiment

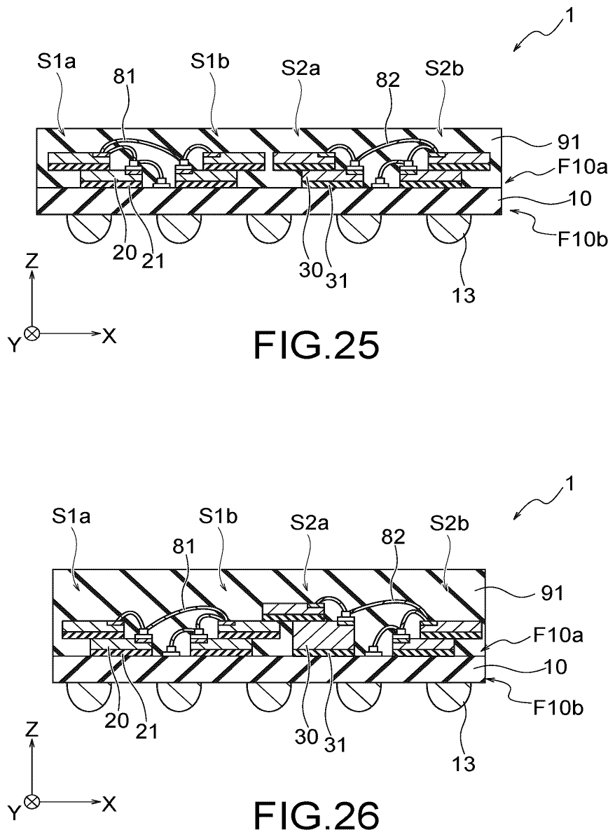

FIG. 25 is a cross sectional view illustrating an example of the configuration of the semiconductor device 1 according to a thirteenth modification of the second embodiment. The thirteenth modification of the second embodiment is different from the second modification of the second embodiment in that connection of the bonding wire 82 is different.

In the example illustrated in FIG. 25, the bonding wire 82 connected to the wiring substrate 10 is connected to the semiconductor chip 20 in the lower stage of the stack S2b.

As in the thirteenth modification of the second embodiment, connection of the bonding wire 82 may be different. With the semiconductor device 1 according to the thirteenth modification of the second embodiment, it is possible to obtain the same effects as in the second modification of the second embodiment.

### Fourteenth Modification of Second Embodiment

FIG. 26 is a cross sectional view illustrating an example of the configuration of the semiconductor device 1 according to a fourteenth modification of the second embodiment. The fourteenth modification of the second embodiment is different from the third modification of the second embodiment in that connection of the bonding wire 81 is different.

In the example illustrated in FIG. 26, the bonding wire 81 connected to the wiring substrate 10 is connected to the semiconductor chip 20 in the lower stage of the stack S1a.

As in the fourteenth modification of the second embodiment, connection of the bonding wire 81 may be different. With the semiconductor device 1 according to the fourteenth modification of the second embodiment, it is possible to obtain the same effects as in the third modification of the second embodiment.

### Third Embodiment

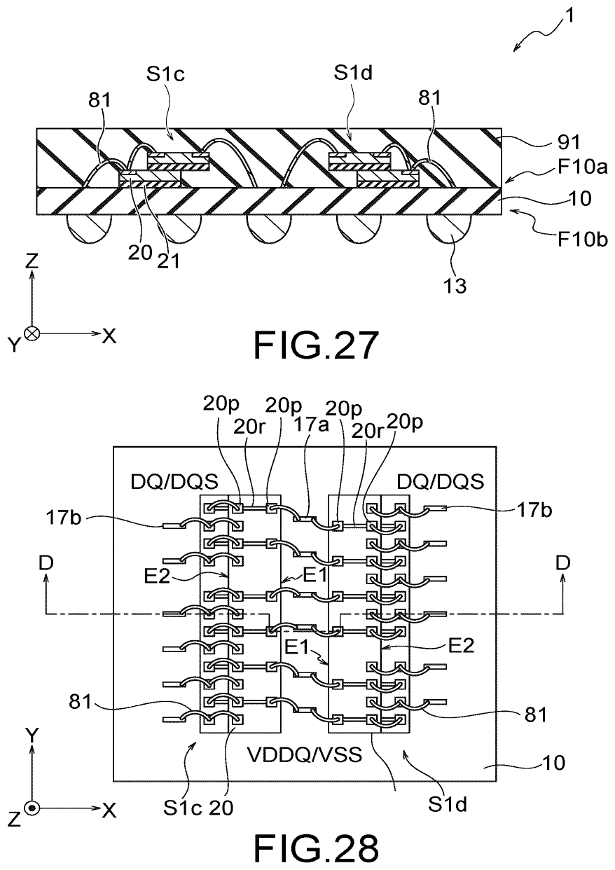

FIG. 27 is a cross sectional view illustrating an example of the configuration of the semiconductor device 1 according to a third embodiment. FIG. 28 is a top view illustrating an example of the configuration of the semiconductor device 1 according to the third embodiment. Line D-D in FIG. 28 indicates a cross section corresponding to the cross sectional view of FIG. 27.

Note that in the example illustrated in FIGS. 27 and 28, the semiconductor chips 30 are not illustrated.

The semiconductor device 1 includes stacks S1c, S1d.

As illustrated in FIG. 28, the stacks S1c, S1d are disposed to be aligned in the short side direction of the semiconductor chips 20.

Each of the stacks S1c, S1d has the semiconductor chips 20 stacked in two stages. Note that the number of the stacked semiconductor chips 20 may be three or more.

The semiconductor chips 20 of the stack Sic are electrically connected to each other through the bonding wire 81. The semiconductor chips 20 of the stack S1d are electrically connected to each other through the bonding wire 81.

The orientations of the stacks S1c, S1d (the orientations of the semiconductor chips 20, 30 when viewed in the Z direction) are opposite to each other. In the example illustrated in FIGS. 27 and 28, the semiconductor chips 20 of the stack S1c are stacked while being displaced in the positive X direction. The semiconductor chips 20 of the stack S1d are stacked while being displaced in the negative X direction.

The semiconductor chips 20 of the stacks Sic, S1d have the pads 20p and wires 20r.

The pads 20p are provided along each of sides E1 and E2 of the semiconductor chips 20, the sides E1 and E2 being opposed to each other when viewed in the direction substantially orthogonal to the surface F10a. Accordingly, wire bonding is performed from both sides of the sides E1, E2 in the plurality of semiconductor chips 20 (the stack S1c or the stack S1d). The sides E1, E2 are, for example, long sides of the semiconductor chips 20. The pad 20p includes Al, for example.

The wire 20r electrically connects the pad 20p provided along the side E1 and the pad 20p provided along the side E2. The wire 20r is a re-wiring layer, for example. The wire 20r includes Al, for example.

Pads 17 include pads 17a and pads 17b. The pads 17a, 17b are provided on the surface F10a so as to sandwich the stack Sic when viewed in the direction substantially orthogonal to the surface F10a. The pads 17a, 17b are provided on the surface F10a so as to sandwich the stack S1d. Accordingly, the pads 17 (the pads 17a, 17b) can be prevented from becoming densely packed.

The pads 17a are provided at positions closer to the side E1 on the surface F10a when viewed in the direction substantially orthogonal to the surface F10a. The pads 17a supply the reference voltage (power VDDQ/ground VSS) to the semiconductor chips 20.

The pads 17a are electrically connected to the two semiconductor chips 20 of the stack Sic through the pads 20p, the wires 20r, and the bonding wires 81. The pads 17a are electrically connected to the two semiconductor chips 20 of the stack S1d through the pads 20p, the wires 20r, and the bonding wires 81.

The pads 17b are provided at positions closer to the side E2 on the surface F10a when viewed in the direction substantially orthogonal to the surface F10a. The pads 17b are pads that allow passage of a signal (DQ/DQS).

The pads 17b are electrically connected to the two semiconductor chips 20 of the stack Sic through the pads 20p and the bonding wires 81. The pads 17b are electrically connected to the two semiconductor chips 20 of the stack S1d through the pads 20p and the bonding wires 81.

The semiconductor chips 20 connected to the pads 17a through the bonding wires 81 are different from the semiconductor chips 20 connected to the pads 17b through the bonding wires 81. Specifically, the semiconductor chips 20 connected to the pads 17a for power/ground are different from the semiconductor chips 20 connected to the pads 17b for the signal.

The pads 17a are disposed between the stack Sic and the stack S1d. The pads 17b are provided on an outer circumferential side of the stacks S1c, S1d. Accordingly, the pads 17a, 17b can be disposed so as to widen the gap between the pads 17a, 17b. Since the pads 17a are disposed between the stack Sic and the stack S1d, the pads 17a can be shared in common by the stack S1c and the stack S1d. Accordingly, the number of the pads 17a can be reduced.

As described above, according to the third embodiment, the pads 20p are provided along each of the sides E1 and E2 opposed to each other when viewed in the direction substantially orthogonal to the surface F10a. Accordingly, wire bonding is performed from both the sides of the sides E1, E2 in the plurality of semiconductor chips 20. As a result, the semiconductor chip 20 can be disposed so as to prevent the pads 17 from being densely packed. Accordingly, the semiconductor chips 20 can be more appropriately disposed in the package.

Note that at least one of the semiconductor chips 20 of the stack Sic may have the pads 20p along each of the sides E1, E2 and the wires 20r. At least one of the semiconductor chips 20 of the stack S1d may have the pads 20p along each of the sides E1, E2 and the wires 20r.

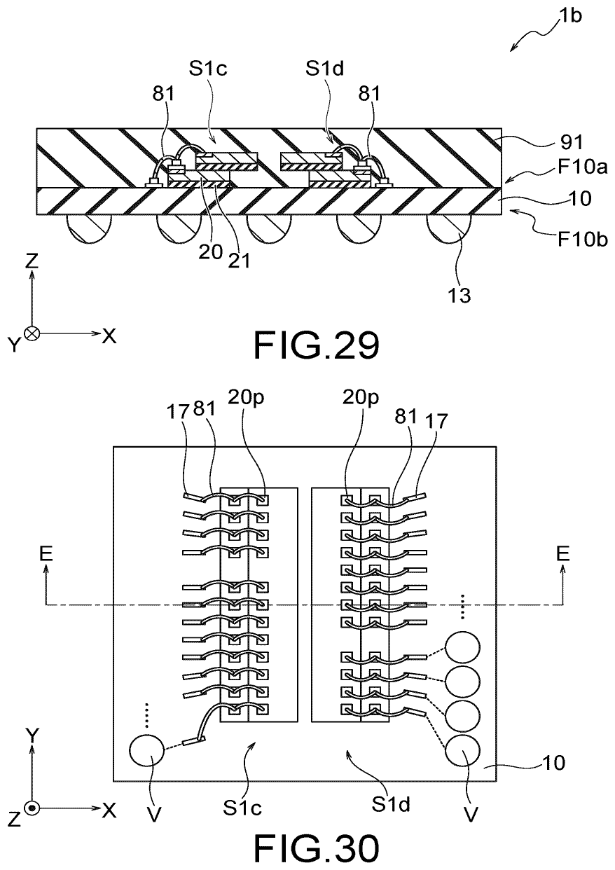

FIG. 29 is a cross sectional view illustrating an example of the configuration of a semiconductor device 1b according to a comparative example of the third embodiment. FIG. 30 is a top view illustrating an example of the configuration of the semiconductor device 1b according to the comparative example of the third embodiment. Line E-E in FIG. 30 indicates a cross section corresponding to the cross sectional view of FIG. 29. The comparative example of the third embodiment is different from the third embodiment in that the pads 20p are provided along one of the sides of the semiconductor chips 20.

As illustrated in FIG. 30, the pads 17 are disposed to be densely packed at a narrow pitch. The bonding wires 81 and the pads 17 connected to the pads 20p in a central part of the semiconductor chip 20 are disposed to be substantially orthogonal (the X direction) to a side of the semiconductor chip 20 when viewed in the Z direction. On the other hand, the bonding wire 81 and the pad 17 connected to the pad 20p at an end of the semiconductor chip 20 are disposed to be tilted from the X direction so as to spread like a fan, for example, when viewed in the Z direction. Accordingly, the bonding wire 81 to be connected to the pad 20p at an end of the semiconductor chip 20 needs to be made long.

When the pads 17 are disposed to be densely packed at a narrow pitch, it is difficult to dispose, in the vicinity of the pads 17, via portions V to be electrically connected to the pads 17. The via portion V is, for example, a through-hole via.

In contrast, since the aspect ratio of the semiconductor chips 20 is relatively high in the third embodiment, it is easy to connect the bonding wires 81 to the pads 20p on both the sides of the sides E1, E2. Accordingly, the pitch of the pads 17 can be widened, which can prevent the pads 17 from becoming densely packed. As a result, the bonding wires 81 can be prevented from increasing in length, and it is possible to make it easier to dispose the via portions V in the vicinity of the pads 17.

### First Modification of Third Embodiment

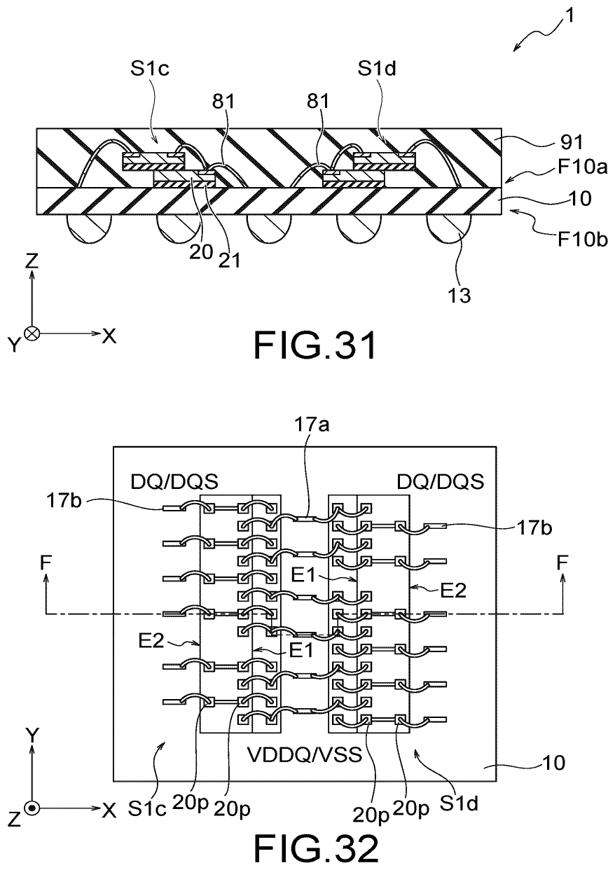

FIG. 31 is a cross sectional view illustrating an example of the configuration of the semiconductor device 1 according to a first modification of the third embodiment. FIG. 32 is a top view illustrating an example of the configuration of the semiconductor device 1 according to the first modification of the third embodiment. Line F-F in FIG. 32 indicates a cross section corresponding to the cross sectional view of FIG. 31. The first modification of the third embodiment is different from the third embodiment in that the stacks S1c, S1d are disposed in different orientations.

In the example illustrated in FIGS. 31 and 32, the semiconductor chips 20 of the stack S1c are stacked while being displaced in the negative X direction. The semiconductor chips 20 of the stack S1d are stacked while being displaced in the positive X direction.

As in the first modification of the third embodiment, the stacks S1c, S1d may be disposed in different orientations. With the semiconductor device 1 according to the first modification of the third embodiment, it is possible to obtain the same effects as in the third embodiment.

### Second Modification of Third Embodiment

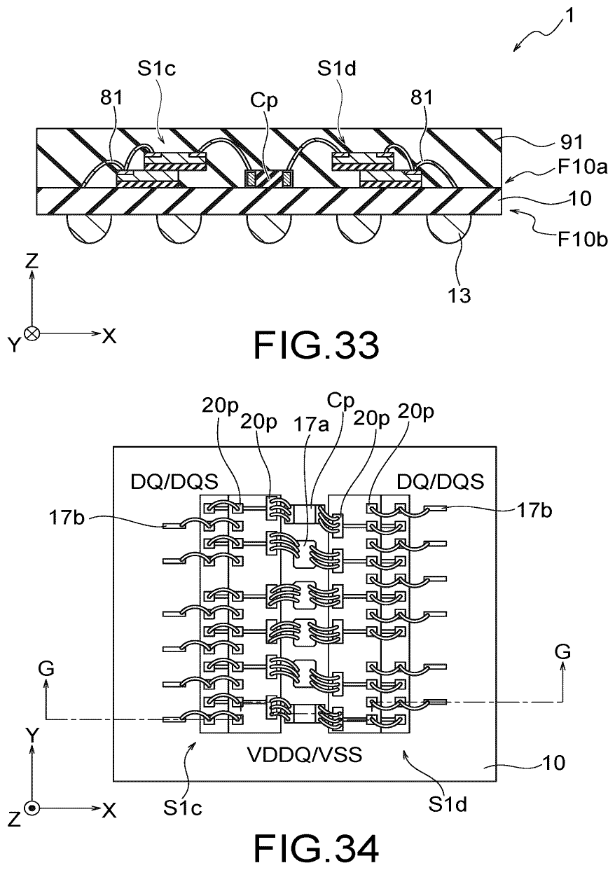

FIG. 33 is a cross sectional view illustrating an example of the configuration of the semiconductor device 1 according to a second modification of the third embodiment. FIG. 34 is a top view illustrating an example of the configuration of the semiconductor device 1 according to the second modification of the third embodiment. Line G-G in FIG. 34 indicates a cross section corresponding to the cross sectional view of FIG. 33. The second modification of the third embodiment is different from the third embodiment in that capacitors Cp are directly wire-bonded and in that the pads 20p and the pads 17 are connected through the plurality of bonding wires 81.

The semiconductor device 1 further includes the capacitors Cp. The capacitors Cp are provided between the stack S1c and the stack S1d. The capacitor Cp has one end electrically connected to the stack S1c through the bonding wire 81. The capacitor Cp has the other end electrically connected to the stack S1d through the bonding wire 81. Surfaces of both ends of the capacitor Cp is treated by gold plating, for example. Accordingly, it is possible to make it easier to perform wire bonding.

The pad 20p and the pad 17 are connected through the plurality of bonding wires 81. Accordingly, the power supply can be enhanced. In the example illustrated in FIG. 34, the pad 20p and the pad 17 are connected through three of the bonding wires 81. Note that the number of the bonding wires 81 is not limited to three.

As in the second modification of the third embodiment, the capacitors Cp may be directly wire-bonded, and the pad 20p and the pad 17 may be connected through the plurality of bonding wires 81. With the semiconductor device 1 according to the second modification of the third embodiment, it is possible to obtain the same effects as in the third embodiment.

### Third Modification of Third Embodiment

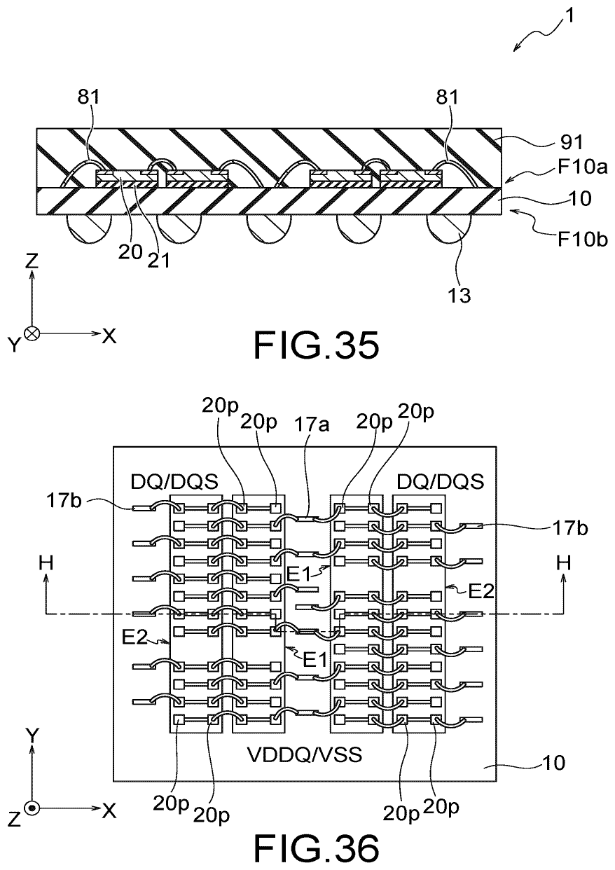

FIG. 35 is a cross sectional view illustrating an example of the configuration of the semiconductor device 1 according to a third modification of the third embodiment. FIG. 36 is a top view illustrating an example of the configuration of the semiconductor device 1 according to the third modification of the third embodiment. Line H-H in FIG. 36 indicates a cross section corresponding to the cross sectional view of FIG. 35. The third modification of the third embodiment is different from the third embodiment in that the plurality of semiconductor chips 20 are not stacked and are provided to be in contact with the wiring substrate 10.

The two semiconductor chips 20 on the left are disposed to be in contact with the wiring substrate 10 and are connected to each other through the bonding wire 81.

The two semiconductor chips 20 on the right are disposed to be in contact with the wiring substrate 10 and are connected to each other through the bonding wire 81.

In the example illustrated in FIG. 36, the two semiconductor chips 20 on the left are disposed such that the orientation of the semiconductor chips 20 when viewed in the Z direction is turned (reversed) 180° with respect to the two semiconductor chips 20 on the right. Specifically, the pads 20p are disposed differently between the two semiconductor chips 20 on the left and the two semiconductor chips 20 on the right.

As in the third modification of the third embodiment, the plurality of semiconductor chips 20 may not be stacked and may be provided to be in contact with the wiring substrate 10. With the semiconductor device 1 according to the third modification of the third embodiment, it is possible to obtain the same effects as in the third embodiment.

### Fourth Modification of Third Embodiment

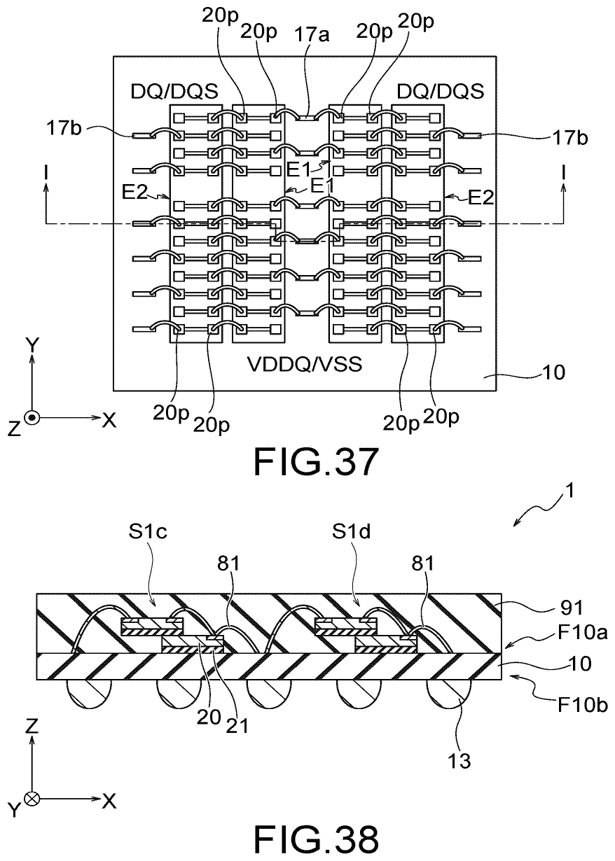

FIG. 37 is a top view illustrating an example of the configuration of the semiconductor device 1 according to a fourth modification of the third embodiment. Line I-I in FIG. 37 indicates a cross section corresponding to the cross sectional view of FIG. 35. The fourth modification of the third embodiment is different from the third modification of the third embodiment in that the four semiconductor chips 20 are disposed in the same orientation.

In the example illustrated in FIG. 37, the orientation of the two semiconductor chips 20 on the left when viewed in the Z direction is the same as the orientation of the two semiconductor chips 20 on the right when viewed in the Z direction. Specifically, the pads 20p are disposed in the same manner in the respective four semiconductor chips 20.

As in the fourth modification of the third embodiment, the four semiconductor chips 20 may be disposed in the same orientation. With the semiconductor device 1 according to the fourth modification of the third embodiment, it is possible to obtain the same effects as in the third modification of the third embodiment.

### Fifth Modification of Third Embodiment

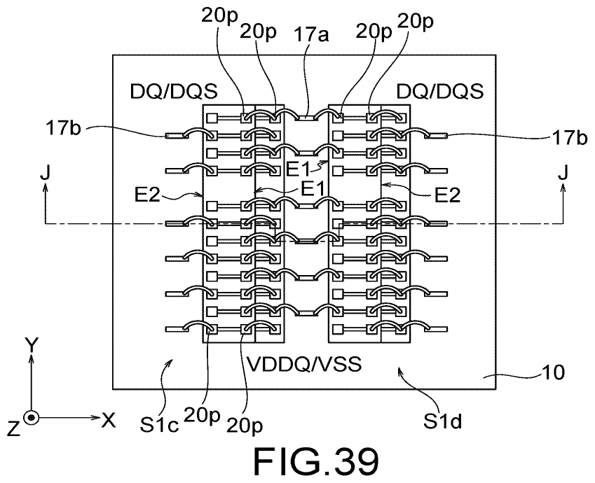

FIG. 38 is a cross sectional view illustrating an example of the configuration of the semiconductor device 1 according to a fifth modification of the third embodiment. FIG. 39 is a top view illustrating an example of the configuration of the semiconductor device 1 according to the fifth modification of the third embodiment. Line J-J in FIG. 39 indicates a cross section corresponding to the cross sectional view of FIG. 38. The fifth modification of the third embodiment is different from the third embodiment in that the stacks S1c, S1d are disposed in the same orientation.

In the example illustrated in FIGS. 38 and 39, the semiconductor chips 20 of the stack S1c are stacked while being displaced in the negative X direction. The semiconductor chips 20 of the stack S1d are stacked while being displaced in the negative X direction.

In the example illustrated in FIG. 39, the orientation of the semiconductor chips 20 of the stack Sic when viewed in the Z direction is the same as the orientation of the semiconductor chips 20 of the stack S1d when viewed in the Z direction. Specifically, the pads 20p are disposed in the same manner in the respective four semiconductor chips 20.

As in the fifth modification of the third embodiment, the stacks S1c, S1d may be disposed in the same orientation. With the semiconductor device 1 according to the fifth modification of the third embodiment, it is possible to obtain the same effects as in the third embodiment.

In the above described embodiments, semiconductor chips having an aspect ratio of more than or equal to three and less than five can be appropriately disposed. Semiconductor chips having an aspect ratio of more than or equal to five and less than ten can be appropriately disposed. Semiconductor chips having an aspect ratio of more than or equal to ten and less than fifteen can be appropriately disposed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate having a first surface;
a plurality of first semiconductor chips stacked while being displaced in a direction substantially parallel to the first surface;
a plurality of first resins provided on respective lower surfaces of the plurality of first semiconductor chips; and
a second semiconductor chip provided on the first surface, wherein
at least one of the plurality of first resins is in contact with an upper surface of the second semiconductor chip.

2. The semiconductor device according to claim 1, wherein the first semiconductor chips are stacked while being displaced in the direction substantially parallel to the first surface by more than or equal to one half of a length of short sides of the first semiconductor chips.

3. The semiconductor device according to claim 1, wherein the first resin in contact with the upper surface of the second semiconductor chip is thicker than remaining ones of the plurality of first resins.

4. A semiconductor device comprising:
a substrate having a first surface;
a first stack provided on the first surface and having a first semiconductor chip;
a second stack provided on the first surface, provided away from the first stack, and having a second semiconductor chip; and
a first wire configured to electrically connect the first semiconductor chip and the second semiconductor chip to each other.

5. The semiconductor device according to claim 4, further comprising a second wire configured to connect the first stack and the substrate.

6. A semiconductor device comprising:
a substrate having a first surface; and
a plurality of first semiconductor chips, wherein
at least one of the first semiconductor chips has an elongated shape when viewed in a direction substantially orthogonal to the first surface, and has a wire configured to electrically connect a plurality of first pads provided along a first side of long sides and a plurality of second pads provided along a second side of the long sides.

7. The semiconductor device according to claim 6, wherein
the substrate further has a third pad and a fourth pad provided on the first surface so as to sandwich the plurality of first semiconductor chips when viewed in the direction substantially orthogonal to the first surface,
the third pad is provided at a position closer to the first side on the first surface when viewed in the direction substantially orthogonal to the first surface and is configured to supply a reference voltage or a ground voltage to the first semiconductor chips, and
the fourth pad is provided at a position closer to the second side on the first surface when viewed in the direction substantially orthogonal to the first surface and is configured to allow passage of a signal.

8. The semiconductor device according to claim 7, wherein
the plurality of first semiconductor chips are electrically connected to one another, and
one of the first semiconductor chips connected to the third pad through a wire is different from one of the first semiconductor chips connected to the fourth pad through a wire.

9. The semiconductor device according to claim 1, wherein a ratio of a width of long sides to a width of short sides of the first semiconductor chips is more than or equal to three and less than five.

10. The semiconductor device according to claim 1, wherein a ratio of a width of long sides to a width of short sides of the first semiconductor chips is more than or equal to five and less than ten.

11. The semiconductor device according to claim 1, wherein a ratio of a width of long sides to a width of short sides of the first semiconductor chips is more than or equal to ten and less than fifteen.

12. The semiconductor device according to claim 4, wherein a ratio of a width of long sides to a width of short sides of the first semiconductor chips is more than or equal to three and less than five.

13. The semiconductor device according to claim 6, wherein a ratio of a width of long sides to a width of short sides of the first semiconductor chips is more than or equal to three and less than five.

14. The semiconductor device according to claim 4, wherein a ratio of a width of long sides to a width of short sides of the first semiconductor chips is more than or equal to five and less than ten.

15. The semiconductor device according to claim 6, wherein a ratio of a width of long sides to a width of short sides of the first semiconductor chips is more than or equal to five and less than ten.

16. The semiconductor device according to claim 4, wherein a ratio of a width of long sides to a width of short sides of the first semiconductor chips is more than or equal to ten and less than fifteen.

17. The semiconductor device according to claim 6, wherein a ratio of a width of long sides to a width of short sides of the first semiconductor chips is more than or equal to ten and less than fifteen.
